(19) United States
(12) Patent Application Publication
(10) Pub. No.: US 2024/0288357 A1
(43) Pub. Date: Aug. 29, 2024

(54) METHOD FOR CONSTRUCTING TIME-VARYING CONSTITUTIVE MODEL OF SEAWATER-AGED GINA GASKET FOR IMMERSED TUBE TUNNEL

(71) Applicant: SHIJIAZHUANG TIEDAO UNIVERSITY, Shijiazhuang City, Hebei (CN)

(72) Inventors: Zhi Nan Hu, Shijiazhuang City (CN); Yi Wen Zong, Shijiazhuang City (CN); Yu Chu Feng, Shijiazhuang City (CN); Yong Gang Du, Shijiazhuang City (CN); Zhi Chun Liu, Shijiazhuang City (CN); Shuo Peng Meng, Shijiazhuang City (CN)

(21) Appl. No.: 18/024,199

(22) PCT Filed: Apr. 19, 2022
(86) PCT No.: PCT/CN2022/087683

§ 371 Date: Mar. 1, 2023

(51) Int. Cl. G01N 17/00; G06F 30/28

(52) U.S. Cl. CPC G01N 17/00; G06F 30/28

(57) ABSTRACT

The present disclosure provides a method for constructing a time-varying constitutive model of a seawater-aged GINA gasket for an immersed tube tunnel and relates to the technical field of research of immersed tube waterproof equipment. The method includes the following steps: obtaining stress relaxation curves at different aging temperatures; determining an aging performance change value P of rubber used for a GINA gasket; determining a stress-strain relation curve of the GINA gasket; obtaining a stress-strain relation curve of a full aging cycle; and constructing a constitutive model of stress relaxation and seawater aging of the GINA gasket. According to the present disclosure, a service state of the GINA gasket can be dynamically monitored, which provides a basis for service life evaluation of the GINA gasket and early warning on a risk of the GINA gasket.

### TECHNICAL FIELD

The present disclosure relates to the technical field of research of immersed tube waterproof equipment, and in particular, to a method for constructing a time-varying constitutive model of a seawater-aged GINA gasket for an immersed tube tunnel.

### BACKGROUND

With the continuous development of China's economy, great achievements have been made in immersed tube tunnels since the reform and opening up. This is especially in the construction of immersed tube tunnels such as Hong Kong-Zhuhai-Macao Bridge and Shenzhen-Zhongshan Bridge, which indicates that China has become a major country in the construction of immersed tube tunnels.

Element joint is a weak link in waterproofing of an immersed tube tunnel, and a GINA gasket, as a main water stop unit of the element joint, directly affects the service performance and service life of the immersed tube tunnel. GINA gaskets started to be used in 1960s. GINA gaskets used in immersed tube tunnels that have been built or under construction in China are from TRELLEBORG and VREDESTEIN, the Netherlands or Yokohama Rubber Co., Ltd., Japan. Currently, no engineering data shows that a GINA gasket can serve well for 100-120 years without any problems. On the one hand, the GINA gasket is in direct contact with seawater, and is subjected to oxidation, swelling, saline-alkali corrosion, mechanical force, biodegradation, and the like, and a polymer of the GINA gasket may be subjected to irreversible physical and chemical reactions such as cross-linking, degradation and cracking, thereby causing performance degradation of the Gina gasket; and on the other hand, under the action of a load, the GINA gasket may produce mechanical performance such as stress relaxation and service performance degradation. In addition, the GINA gasket cannot be repaired or replaced during an operation period, and once large-scale water leakage occurs, incalculable consequences and losses may occur. Therefore, it is of great research significance to perform dynamic monitoring, evaluation and early warning of a service state of the GINA gasket and predict the service life of the GINA gasket, and determine an aging constitutive relation of GINA gasket aging under a coupling effect of an environment and a load in advance.

### SUMMARY

The present application provides a method for constructing a time-varying constitutive model of a seawater-aged GINA gasket for an immersed tube tunnel, which represents a rubber constitutive relation of stress relaxation and seawater aging characteristics of a GINA gasket based on a Mooney-Rivlin model.

According to the present application, a compression test is first performed on each selected GINA gasket test piece; when a compression amount reaches a designed compression amount, the selected GINA gasket test piece is placed in a designed seawater aging test cabin for a stress relaxation test, and material deterioration and mechanical property degradation of the GINA gasket are observed under the combined action of seawater and a load; an unaged GINA gasket is cooled in liquid nitrogen and cut into a dumbbell shape, and a uniaxial tensile test is performed to test a stress-strain relation of the unaged GINA gasket; and a uniaxial tensile test process is simulated by using a Mooney-Rivlin model, to construct a constitutive model of stress relaxation and seawater aging of the GINA gasket.

The present application adopts the following specific technical solution:

A method for constructing a time-varying constitutive model of a seawater-aged GINA gasket for an immersed tube tunnel includes the following steps:
(1) selecting GINA gasket test pieces, and performing an accelerated seawater aging test of each GINA gasket test piece at different temperatures under a designed compression amount, to obtain stress relaxation curves at different aging temperatures;
(2) determining a contact stress σ of the aged GINA gasket and an initial contact stress σ₀ of the GINA gasket based on the stress relaxation curves in step (1), and determining an aging coefficient k of the GINA gasket based on k=σ/σ₀; and determining, based on P=σ−σ₀, an aging performance change value P of rubber used for the GINA gasket;
(3) obtaining a curve of lnP changing with a time t at normal temperature based on a time-temperature superposition principle, to obtain an equation P-exp(f(t)), where f(t) is a function of the aging performance change value P changing with the time t; and determining P=(1−k)σ₀ based on a correlation between the aging coefficient k of the GINA gasket and the aging performance change value P of the rubber used for the GINA gasket, that is, a normal temperature aging coefficient k_{Normal}=1−exp(f(t))/σ₀ of the GINA gasket is obtained;
(4) performing a uniaxial tensile test of the GINA gasket at an ambient temperature of 23° C. and a tensile speed of 500 mm/min, and determining a stress-strain relation curve of the GINA gasket;
(5) modifying the stress-strain relation curve in step (4) by using the normal temperature aging coefficient k_{Normal} of the GINA gasket, to obtain a stress-strain relation curve of a full aging cycle; and
(6) constructing a constitutive model of stress relaxation and seawater aging of the GINA gasket with reference to a Mooney-Rivlin model based on the stress-strain relation curve of the full aging cycle in step (5):

$$σ = 2 ( {λ}^{2} - {λ}^{- 1} ) ( f ( t ) + g ( t ) {λ}^{- 1} ) ,$$

where t is an aging time; λ is an elongation ratio of the GINA gasket; f(t) is a function of C₁₀ changing with the time t; g(t) is a function of C₀₁ changing with the time t; and C₁₀ and C₀₁ are Rivlin coefficients of the Mooney-Rivlin model, with values determined by the stress-strain relation curve of the full aging cycle.

Further, step (6) specifically includes:
(6.1) determining εᵢ based on the uniaxial tensile test of the GINA gasket in step (4), determining three elongation ratios λᵢ of the GINA gasket based on εᵢ, which are denoted as λ₁, λ₂, and λ₃, and calculating Green strain invariants I₁ and I₂, as follows:

$${λ}_{i} = 1 + {ε}_{i} , \qquad ( 1 )$$

$${I}_{1} = {λ}_{1}^{2} + {λ}_{2}^{2} + {λ}_{3}^{2} , and \qquad ( 2 )$$

$${I}_{2} = {λ}_{1}^{2} {λ}_{2}^{2} + {λ}_{2}^{2} {λ}_{3}^{2} + {λ}_{1}^{2} {λ}_{3}^{2} , \qquad ( 3 )$$

where I₁ is a first strain invariant, and I₂ is a second strain invariant; λ₁, λ₂ and λ₃ represent an elongation ratio in an X-axis direction, an elongation ratio in a Y-axis direction, and an elongation ratio in a Z-axis direction respectively; εᵢ is a strain, i=1, 2 or 3, where ε₁ is a strain in the X-axis direction, ε₂ is a strain in the Y-axis direction, and ε₃ is a strain in the Z-axis direction;
(6.2) obtaining a strain energy density W as follows based on the Mooney-Rivlin model:

$$W = {C}_{10} ( {I}_{1} - 3 ) + {C}_{01} ( {I}_{2} - 3 ) \qquad ( 4 )$$

where C₁₀ and C₀₁ are Rivlin coefficients of the Mooney-Rivlin model, with values determined by the stress-strain relation curve of the full aging cycle;
(6.3) obtaining, by using a relation between a Kirchhoff stress and a Green strain:

$$σ = \frac{\partial W}{{\partial }_{{ε}_{i}}} = \frac{\partial W}{\partial {I}_{1}} \frac{\partial {I}_{1}}{{\partial }_{{ε}_{i}}} + \frac{\partial W}{\partial {I}_{2}} \frac{\partial {I}_{2}}{{\partial }_{{ε}_{i}}} ,$$

a relation between the contact stress σ of the aged GINA gasket and the elongation ratio λ as follows:

$$σ = 2 ( {λ}^{2} - {λ}^{- 1} ) ( \frac{\partial W}{\partial {I}_{1}} + \frac{1}{λ} \frac{\partial W}{\partial {I}_{2}} ) \qquad ( 5 )$$

calculating partial derivatives of I₁ and I₂ by using formula (4), to obtain

$$\frac{\partial W}{\partial {I}_{1}} = {C}_{10}$$

$$and$$

$$\frac{\partial W}{\partial {I}_{2}} = {C}_{01} ,$$

and then obtaining a relation between the contact stress σ of the aged GINA gasket and the elongation ratio λ as follows:

$$σ = 2 ( {λ}^{2} - {λ}^{- 1} ) ( {C}_{10} + {C}_{01} {λ}^{- 1} ) , \qquad ( 6 )$$

(6.4) identifying parameters of formula (6) by using a nonlinear least square method based on the stress-strain relation curve of the full aging cycle by means of Origin software, to obtain values of C₁₀ and C₀₁ in a full life cycle tᵢ, obtaining functions f(t) and g(t) of C₁₀ and C₀₁ changing with a time based on curves of C₁₀ and C₀₁ changing with the aging time, and then constructing the constitutive model of stress relaxation and seawater aging of the GINA gasket:

$$σ = 2 ( {λ}^{2} - {λ}^{- 1} ) ( f ( t ) + g ( t ) {λ}^{- 1} ) . \qquad ( 7 )$$

Further, in step (1), conditions of the accelerated seawater aging test are as follows:

the gasket with a Shore hardness of 50 HS is placed on a bottom plate, and restrained by a ballast plate and a pressure strip; with reference to a TB/T2843-2010 standard, a press with a rated load of 3000 kN is used to add a load to the gasket; after a compression amount reaches 125.0 mm, the ballast plate is controlled by using a medium plate, a liquid gas pressure sensor is placed on the medium plate and pressed by using a top plate; the top plate, the medium plate and the bottom plate are fixed and then integrally placed in a sealed polypropylene plastic cabin 1, which is filled with natural seawater by ⅔, and a contact stress of the GINA gasket in the seawater is collected in real time within a range of 50-80° C.

Further, specific conditions of the uniaxial tensile test in step (4) are as follows:
the GINA gasket after seawater aging in step (1) is taken out, cooled with liquid nitrogen, and prepared into a dumbbell-shaped test piece based on GB/T528-2009, the test piece is coated with a lubricant, and the tensile test is performed by using a universal testing machine at a normal temperature of 23° ° C. at a speed of 500 mm/min.

Further, the dumbbell-shaped test piece has a total length of 100.0 mm and a thickness of 2.0 mm, and a test section has an initial test length of 20.0 mm.

The present application has the following beneficial effects:

(1) According to the present disclosure, a constitutive model of stress relaxation and seawater aging of a GINA gasket is constructed by comprehensively considering influencing factors, a seawater temperature and an aging time, based on a Mooney-Rivlin model, true simulation can be implemented, and a service state of the GINA gasket can be dynamically monitored, which provides a basis for service life evaluation of the GINA gasket and early warning on a risk of the GINA gasket.

(2) Through investigation, it can be learned that currently, there is no material constitutive model specifically reflecting a service state of a GINA gasket, and conventional rubber constitutive models are mostly static constitutive models, and cannot reflect time-varying characteristics of a stress-strain change of a GINA gasket material with a time. The technical advantages of the constitutive model are as follows. On the one hand, according to the present disclosure, a stress relaxation test and a uniaxial tensile test of the GINA gasket are performed under the combined action of seawater and a load, and then simulation is performed by using the Mooney-Rivlin model and based on obtained test data, thereby constructing a time-varying constitutive model of stress relaxation and seawater aging of the GINA gasket. The constitutive model is constructed based on an actual operating environment and operating conditions of the GINA gasket, so that more accurate and practical predicted data of the service life of the GINA gasket can be obtained. On the other hand, the constitutive model is simple to construct and has a clear process, high accuracy, and high implementability, can represent a change of a constitutive relation of the GINA gasket with a time, and can implement dynamic monitoring of the service state of GINA gasket, thereby providing a good basis for service life evaluation of the GINA gasket.

### BRIEF DESCRIPTION OF THE DRAWINGS

FIG. 1 is a planar graph of a seawater aging test cabin;

FIG. 2 is a three-dimensional diagram of a seawater aging test cabin;

FIG. 3 shows GINA gasket test pieces with different hardness;

FIG. 4 shows stress relaxation curves of a GINA gasket;

FIG. 5 shows a relation between an aging coefficient k and an aging time;

FIG. 6 is a stress-strain relation curve graph;

FIG. 7 shows a stress-strain curve of a full aging cycle; and

FIG. 8A shows a curve of C₁₀ changing with an aging time, and FIG. 8B shows a curve of C₀₁ changing with the aging time,

where a sealed polypropylene plastic cabin 1, a liquid gas pressure sensor 2 and a GINA gasket 3 are provided.

### DETAILED DESCRIPTION OF THE EMBODIMENTS

To make the objectives, technical solutions, and advantages of the present application clearer, the present application is further described in detail below with reference to the accompanying drawings and embodiments. It should be understood that the specific embodiments described herein are only used to explain the present application, but not to limit the present application. That is, the described embodiments are only some rather than all embodiments of the present application.

Therefore, the following detailed description of the embodiments of the present application is not intended to limit the protection scope of the present application, but merely to represent selected embodiments of the present application. All other embodiments obtained by those of ordinary skill in the art based on the embodiments of the present application without creative efforts should fall within the protection scope of the present application.

It should be noted that the term “comprise”, “include”, or any other variant thereof is intended to encompass a non-exclusive inclusion, so that a method that includes a series of elements includes not only those elements, but also other elements not explicitly listed, or further includes inherent or conventional elements of the method.

The technical solutions of the present application are further described with reference to the accompanying drawings and embodiments.

A method for constructing a time-varying constitutive model of a seawater-aged GINA gasket for an immersed tube tunnel according to the present application includes the following steps.

(1) Select GINA gasket test pieces, and perform an accelerated seawater aging test of each GINA gasket test piece at different temperatures under a designed compression amount, where conditions of the accelerated seawater aging test are as follows: the gasket with a Shore hardness of 50 HS is placed on a bottom plate, and restrained by a ballast plate and a pressure strip; with reference to a TB/T2843-2010 standard, a press with a rated load of 3000 kN is used to add a load to the gasket; after a compression amount reaches 125.0 mm, the ballast plate is controlled by using a medium plate, a liquid gas pressure sensor 2 is placed on the medium plate and pressed by using a top plate; the top plate, the medium plate and the bottom plate are fixed and then integrally placed in a sealed polypropylene plastic cabin 1, which is filled with natural seawater by ⅔, and a contact stress of the GINA gasket 3 in the seawater is collected in real time within a range of 50-80° ° C., to obtain stress relaxation curves at different aging temperatures.

(2) Determine a contact stress σ of the aged GINA gasket and an initial contact stress σ₀ of the GINA gasket based on the stress relaxation curves in step (1), and determine an aging coefficient k of the GINA gasket 3 based on k=σ/σ₀; and determine, based on P=σ−σ₀, an aging performance change value P of rubber used for the GINA gasket 3.

(3) Obtain a curve of lnP changing with a time t at normal temperature based on a time-temperature superposition principle, to obtain an equation P=exp(f(t)), determine P=(1−k)σ₀ based on a correlation between the aging coefficient k of the GINA gasket 3 and the aging performance change value P of the rubber used for the GINA gasket 3, that is, a normal temperature aging coefficient k_{Normal}=1−exp(f(t))/σ₀ of the GINA gasket 3 is obtained, where f(t) represents a function of P changing with a time.

(4) Perform a uniaxial tensile test of the GINA gasket 3 at an ambient temperature of 23° C. and a tensile speed of 500 mm/min, that is, the GINA gasket 3 after seawater aging is taken out, cooled with liquid nitrogen, and prepared into a dumbbell-shaped test piece based on GB/T528-2009, the test piece is coated with a lubricant, and the tensile test is performed by using a universal testing machine at a normal temperature of 23° C. at a speed of 500 mm/min; and determine a stress-strain relation curve of the GINA gasket.

(5) Modify the stress-strain relation curve in step (4) by using the normal temperature aging coefficient k_{Normal} of the GINA gasket, to obtain a stress-strain relation curve of a full aging cycle.

(6) Construct a constitutive model of stress relaxation and seawater aging of the GINA gasket with reference to a Mooney-Rivlin model based on the stress-strain relation curve of the full aging cycle in step (5):

$$σ = 2 ( {λ}^{2} - {λ}^{- 1} ) ( f ( t ) + g ( t ) {λ}^{- 1} ) ,$$

where t is an aging time; λ is an elongation ratio of the GINA gasket; f(t) is a function of C₁₀ changing with the time t; g(t) is a function of C₀₁ changing with the time t; and C₁₀ and C₀₁ are Rivlin coefficients of the Mooney-Rivlin model, with values determined by the stress-strain relation curve of the full aging cycle.

Step (6) specifically includes the following steps.

(6.1) Determine εᵢ based on the uniaxial tensile test of the GINA gasket 3 in step (4), determine elongation ratios λ of the GINA gasket in three directions based on εᵢ, which are denoted as λ₁, λ₂, and λ₃, where εᵢ is a strain, i=1, 2 or 3, ε₁ is a strain in an X-axis direction, ε₂ is a strain in a Y-axis direction, and ε₃ is a strain in a Z-axis direction; λ₁ is an elongation ratio in the X-axis direction, λ₂ is an elongation ratio in the Y-axis direction, and λ₃ is an elongation ratio in the Z-axis direction; and calculate Green strain invariants I₁ and I₂, as follows:

$${λ}_{i} = 1 + {ε}_{i} , \qquad ( 1 )$$

$${I}_{1} = {λ}_{1}^{2} + {λ}_{2}^{2} + {λ}_{3}^{2} , and \qquad ( 2 )$$

$${I}_{2} = {λ}_{1}^{2} {λ}_{2}^{2} + {λ}_{2}^{2} {λ}_{3}^{2} + {λ}_{1}^{2} {λ}_{3}^{2} , \qquad ( 3 )$$

where I₁ is a first strain invariant, and I₂ is a second strain invariant.

(6.2) Expand a strain energy function of hyperelastic rubber by using a Taylor formula to obtain the following:

$$W = {\sum }_{i + j = 1}^{N} {{C}_{ij} ( \overline{{I}_{1}} - 3 )}^{i} {( \overline{{I}_{2}} - 3 )}^{j} + {\sum }_{i = 1}^{N} \frac{1}{{D}_{i}} {( J - 1 )}^{2 i}$$

It is assumed that a rubber material used for the GINA gasket 3 is incompressible, J=1, and Cᵢⱼ is a rubber characteristic parameter: i+j=1, that is, when i=1, j=0; and when i=0, j=1.

For a complete polynomial, when N=1, strain energy of the remaining linear part is retained, that is, a strain energy density function of the Mooney-Rivlin constitutive model is obtained as follows:

$$W = {C}_{10} ( {I}_{1} - 3 ) + {C}_{01} ( {I}_{2} - 3 ) \qquad ( 4 )$$

where C₁₀ and C₀₁ are Rivlin coefficients of the Mooney-Rivlin model, with values determined by the stress-strain relation curve of the full aging cycle.
(6.3) Calculate a partial derivative of the elongation ratio to obtain a Kirchhoff stress, and obtain, by using a relation between the Kirchhoff stress and a Green strain:

$$σ = \frac{\partial W}{\partial {ε}_{i}} = \frac{\partial W}{\partial {I}_{1}} \frac{\partial {I}_{1}}{\partial {ε}_{i}} + \frac{\partial W}{\partial {I}_{2}} \frac{\partial {I}_{2}}{\partial {ε}_{i}} ,$$

a relation between the contact stress σ of the aged GINA gasket and the elongation ratio λ as follows with reference to λ₂²=λ₃²=λ₁⁻¹:

$$σ = 2 ( {λ}^{2} - {λ}^{- 1} ) ( \frac{\partial W}{\partial {I}_{1}} + \frac{1}{λ} \frac{\partial W}{\partial {I}_{2}} ) . \qquad ( 5 )$$

Calculate partial derivatives of I₁ and I₂ by using formula (4), to obtain

$$\frac{\partial W}{\partial {I}_{1}} = {C}_{10}$$

$$and$$

$$\frac{\partial W}{\partial {I}_{2}} = {C}_{01} ,$$

and then obtain a relation between the contact stress σ of the aged GINA gasket and the elongation ratio λ as follows:

$$σ = 2 ( {λ}^{2} - {λ}^{- 1} ) ( {C}_{10} + {C}_{01} {λ}^{- 1} ) . \qquad ( 6 )$$

(6.4) Identify parameters of formula (6) by using a nonlinear least square method based on the stress-strain relation curve of the full aging cycle by means of Origin software, to obtain values of C₁₀ and C₀₁ in a full life cycle tᵢ, obtain functions f(t) and g(t) of C₁₀ and C₀₁ changing with a time based on curves of C₁₀ and C₀₁ changing with the aging time, and then construct the constitutive model of stress relaxation and seawater aging of the GINA gasket:

$$σ = 2 ( {λ}^{2} - {λ}^{- 1} ) ( f ( t ) + g ( t ) {λ}^{- 1} ) . \qquad ( 7 )$$

The following embodiment is taken as an example for description.

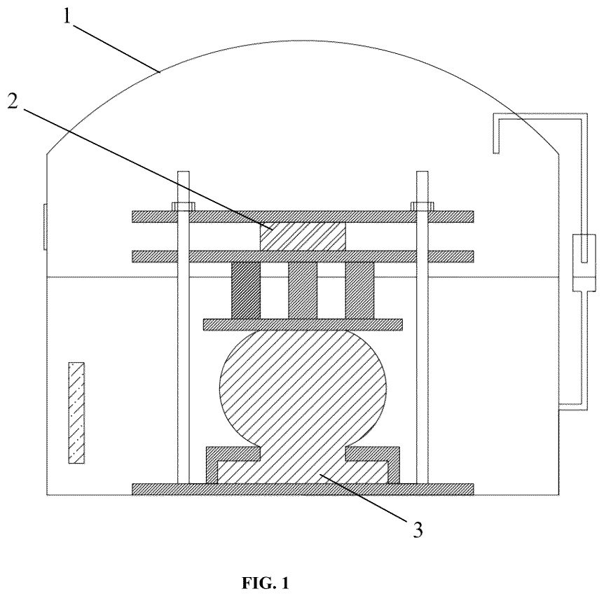

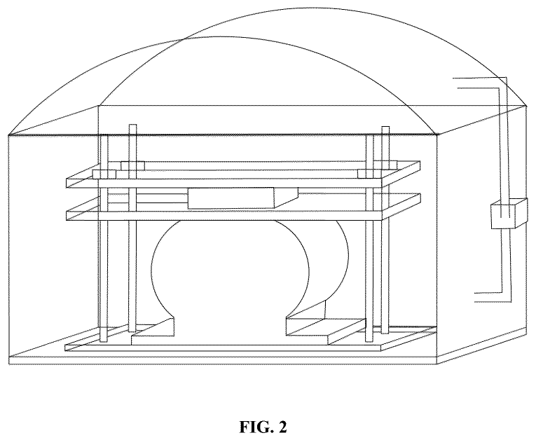

(1) A GINA gasket 3 with a length of 20.0 cm×a width of 29.5 cm×a height of 27.5 cm was placed on a bottom plate with a length of 60.0 cm×a width of 35.0 cm×a thickness of 20.0 cm, and restrained by a ballast plate with a length of 35.0 cm×a width of 35.0 cm×a thickness of 20.0 cm and a pressure strip; with reference to a TB/T2843-2010 standard, a press with a rated load of 3000 kN was used to add a load to the GINA gasket 3 with a Shore hardness of 50 HS; after a compression amount of the GINA gasket reached 125.0 mm, the ballast plate was controlled by using a medium plate with a length of 60.0 cm×a width of 35.0 cmx a thickness of 20.0 cm, a Siemens QBE2103-P10 liquid gas pressure sensor 2 was placed on the medium plate and pressed by using a top plate with a length of 60.0 cm×a width of 35.0 cm×a thickness of 20.0 cm; and the top plate, the medium plate and the bottom plate were fixed by Q235 tooling bolts with a size of M30. A device was placed in a sealed polypropylene plastic cabin 1 with a designed length of 80.0 cm×width of 50.0 cm×height of 90.0 cm, and filled with natural seawater by ⅔, as shown in FIG. 1 and FIG. 2.

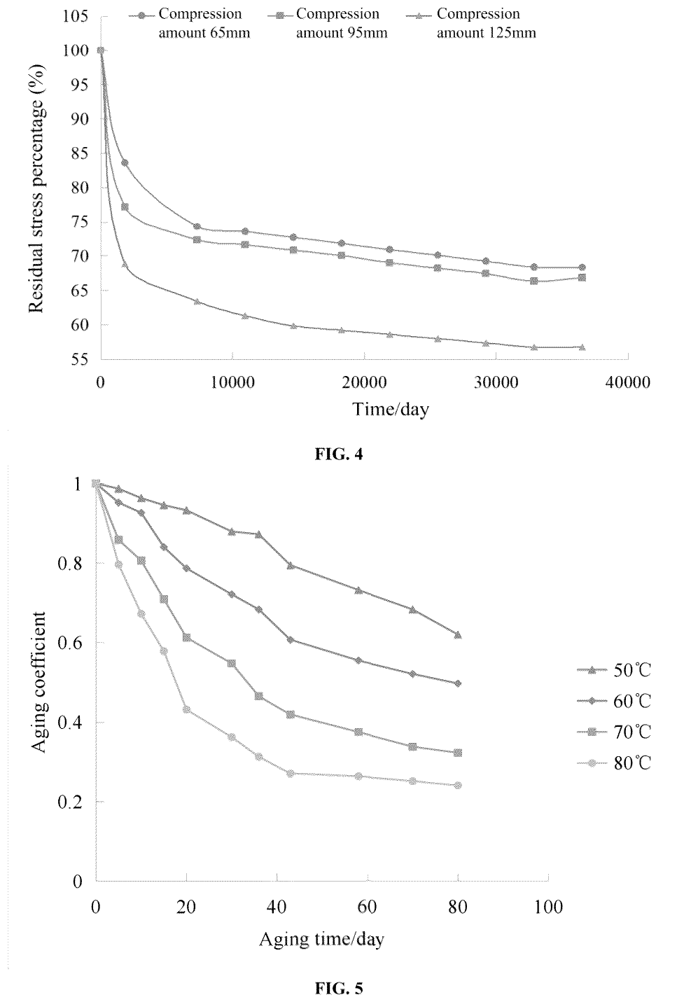

Attenuation of contact stress relaxation of the GINA gasket 3 in seawater at 50° C., 60° C. and 70° C. was measured in the sealed aging polypropylene plastic cabin 1 in real time by the liquid gas pressure sensor 2, and stress relaxation curves at different aging temperatures were obtained. Results are shown in FIG. 4.

(2) A contact stress σ of the aged GINA gasket and an initial contact stress σ₀ of the GINA gasket were determined based on the stress relaxation curves in step (1), and an aging coefficient k of the GINA gasket was determined based on k=σ/σ₀; and an aging performance change value P of rubber used for the GINA gasket was determine based on P=σ−σ₀.

(3) A curve of lnP changing with a time t at normal temperature was obtained through fitting based on a time-temperature superposition principle, to obtain P=exp(f(t)), and obtain curves of the aging coefficient k with an aging time at different temperatures, referring to FIG. 5, P=(1−k)σ₀ was obtained based on k=σ/σ₀=(σ₀−P)/σ₀, and then a normal temperature aging coefficient k_{Normal}=1−exp(f(t))/σ₀ of the GINA gasket was determined.

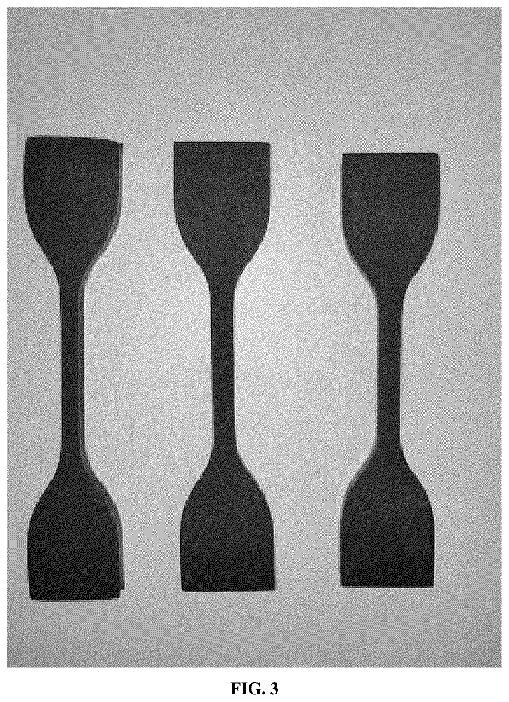

(4) A uniaxial tensile test of the GINA gasket 3 was performed, and the GINA gasket was taken out from a seawater aging test cabin, cooled with liquid nitrogen, and prepared into dumbbell-shaped test pieces (each test piece had a total length of 100.0 mm and a thickness of 2.0 mm, and a test piece test section had an initial test length of 20.0 mm) by using a punching and milling cutter based on GB/T528-2009, as shown in FIG. 3.

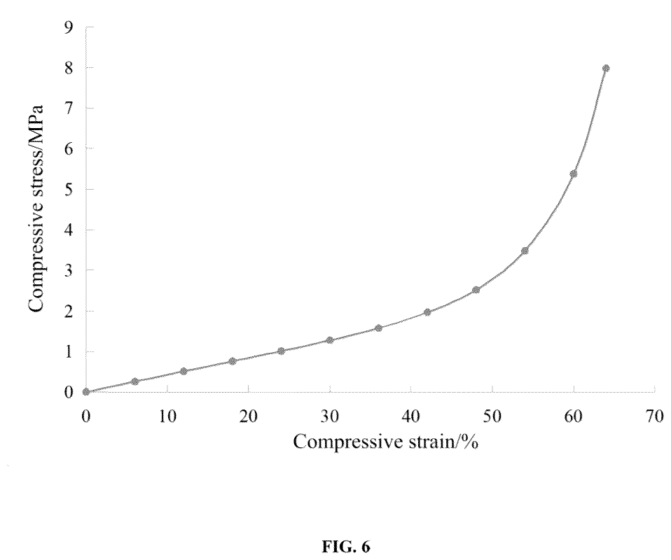

The uniaxial tensile test of the GINA gasket 3 was performed by using an MTSYAW6306 electro-hydraulic servo universal testing machine (3000 kN) from USA. First the selected test pieces were coated with a lubricant to reduce friction, and the tensile test was performed at a normal temperature of 23° C. at a speed of 500 mm/min. A force measured by the sensor on a pressure plate was divided by an original cross-sectional area of the GINA gasket 3, and displacement measured by a displacement sensor was divided by an original height of the GINA gasket, to obtain a stress-strain relation curve in FIG. 6.

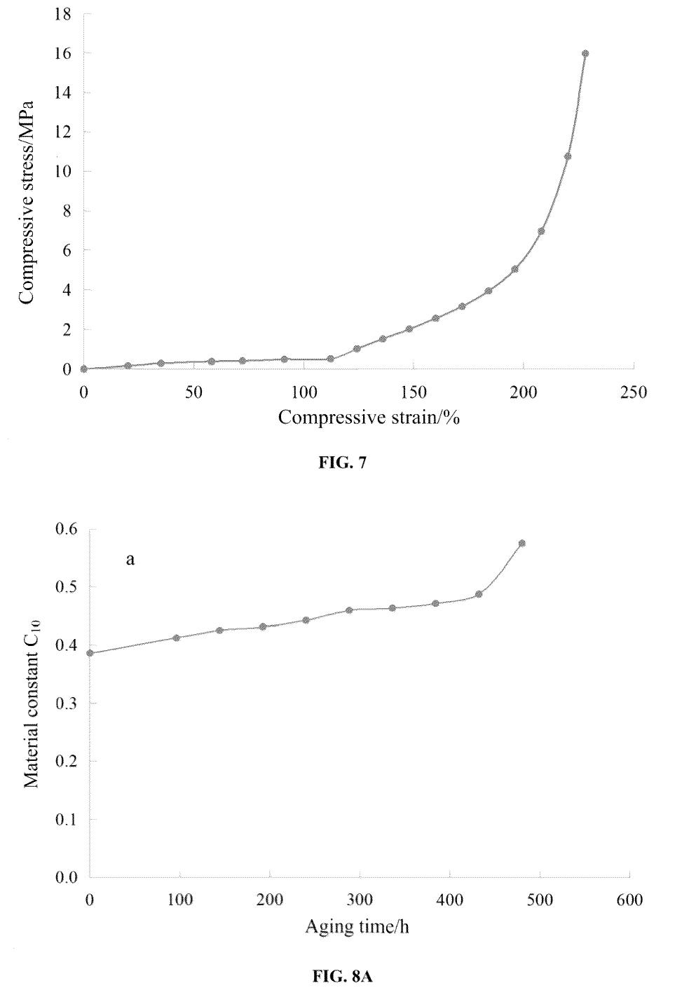

(5) The curve was modified by using the normal temperature aging coefficient k_{Normal} based on the stress-strain relation curve obtained from the uniaxial tensile test, to obtain a stress-strain relation curve of a full aging cycle, as shown in FIG. 7.

(6) An elongation ratio λ of the GINA gasket was determined based on the stress-strain relation curve of the full aging cycle in step (5), and a constitutive model of stress relaxation and seawater aging of the GINA gasket was constructed by using the Mooney-Rivlin model, specifically as follows.

(6.1) Green strain invariants I₁ and I₂ were obtained by using elongation ratios λ₁, λ₂ and λ₃ in three directions, as shown in formula (1) to formula (3):

$${λ}_{i} = 1 + {ε}_{i} , \qquad ( 1 )$$

$${I}_{1} = {λ}_{1}^{2} + {λ}_{2}^{2} + {λ}_{3}^{2} , and \qquad ( 2 )$$

$${I}_{2} = {λ}_{1}^{2} {λ}_{2}^{2} + {λ}_{2}^{2} {λ}_{3}^{2} + {λ}_{1}^{2} {λ}_{3}^{2} , \qquad ( 3 )$$

where in a uniaxial tensile process, ε₂=ε₃=−1, that is, λ₂=λ₃=0, and then λ₁=λ₁, that is, λ₁=ε₁+1.

(6.2) A strain energy density expression was determined as follows based on the Green strain invariants I₁ and I₂:

$$W = {C}_{10} ( {I}_{1} - 3 ) + {C}_{01} ( {I}_{2} - 3 ) \qquad ( 4 )$$

a strain energy density was calculated; and
The strain energy density was approximately fitted as follows by using a strain energy density function formula:

$$W = 0.386 {e}^{0.0008 t} ( {I}_{1} - 3 ) + ( - 0.203 {e}^{0.0008 t} ) ( {I}_{2} - 3 ) + \frac{1}{{D}_{1}} {( J - 1 )}^{2}$$

where C₁₀=0.386e^{0.0008t}, C₀₁=−0.203e^{0.0008t}, and t is a test time (h); it is assumed that a rubber material used for the GINA gasket 3 is incompressible, J=1, and Cᵢⱼ is a rubber characteristic parameter: i+j=1, that is, when i=1, j=0; and when i=0, j=1.

(6.3) A partial derivative of the elongation ratio was calculated to obtain a Kirchhoff stress, and by using a relation between the Kirchhoff stress and a Green strain:

$$σ = \frac{\partial W}{\partial {ε}_{i}} = \frac{\partial W}{\partial {I}_{1}} \frac{\partial {I}_{1}}{\partial {ε}_{i}} + \frac{\partial W}{\partial {I}_{2}} \frac{\partial {I}_{2}}{\partial {ε}_{i}} ,$$

and the elongation ratio λ was obtained as follows with reference to λ₂²=λ₃²=λ₁⁻¹:

$$σ = 2 ( {λ}^{2} - {λ}^{1} ) ( \frac{\partial W}{\partial {I}_{1}} + \frac{1}{λ} \frac{\partial W}{\partial {I}_{2}} ) . \qquad ( 5 )$$

Referring to Table 1, partial derivatives of I₁ and I₂ were calculated by using formula (5), to obtain

$$\frac{\partial W}{\partial {I}_{1}} = {C}_{10} and \frac{\partial W}{\partial {I}_{2}} = {C}_{01} ,$$

and then a relation between the contact stress σ of the aged GINA gasket and the elongation ratio λ was obtained as follows:

$$σ = 2 ( {λ}^{2} - {λ}^{1} ) ( {C}_{10} + {C}_{01} {λ}^{- 1} ) . \qquad ( 6 )$$

TABLE 1
Stress-strain values and tensile ratios obtained from the uniaxial tensile test

| σ | 0.00 | 0.26 | 0.51 | 0.76 | 1.01 | 1.28 | 1.58 | 1.97 | 2.52 | 3.48 | 5.38 | 7.98 |
|---|---|---|---|---|---|---|---|---|---|---|---|---|
| ε | 0.00 | 0.06 | 0.12 | 0.18 | 0.24 | 0.30 | 0.36 | 0.42 | 0.48 | 0.54 | 0.60 | 0.64 |
| λ = ε + 1 | 1.00 | 1.06 | 1.12 | 1.18 | 1.24 | 1.30 | 1.36 | 1.42 | 1.48 | 1.54 | 1.60 | 1.64 |

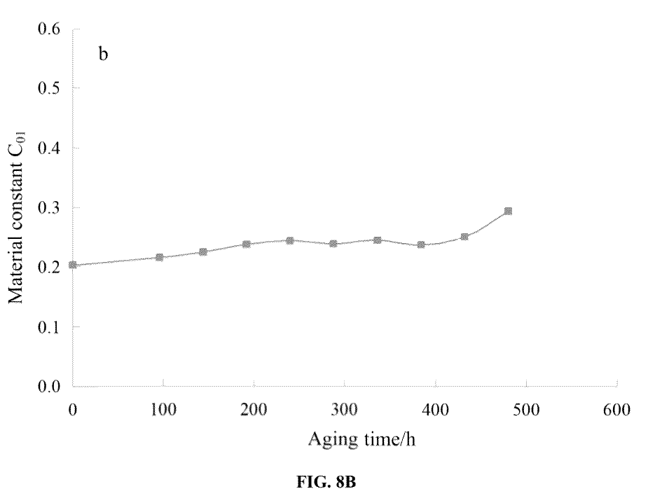

(6.4) Parameters of formula (7) were identified by using a nonlinear least square method based on the stress-strain relation curve of the full aging cycle by means of Origin software, referring to Table 2, to obtain values of C₁₀ and C₀₁ at different aging times tᵢ, and curves of C₁₀ and C₀₁ changing with the aging time were determined, referring to FIG. 8A-B.

TABLE 2
Changes of material constants C₁₀ and C₀₁ with the aging time

| Aging time/h | Material constant C₁₀ | Material constant C₀₁ |
|---|---|---|
| 0 | 0.386 | 0.203 |
| 96 | 0.412 | 0.216 |
| 144 | 0.425 | 0.225 |
| 192 | 0.431 | 0.238 |
| 240 | 0.442 | 0.244 |
| 288 | 0.459 | 0.239 |
| 336 | 0.463 | 0.245 |
| 384 | 0.471 | 0.237 |
| 432 | 0.487 | 0.251 |
| 480 | 0.575 | 0.294 |

Based on the curves of C₁₀ and C₀₁ changing with the aging time, functions f(t) and g(t) of C₁₀ and C₀₁ changing with a time are regressed, and then an aging and time-varying constitutive model of stress relaxation and seawater aging of a GINA gasket was obtained:

$$σ = 2 ( {λ}^{2} - {λ}^{1} ) ( f ( t ) + g ( t ) {λ}^{- 1} ) . \qquad ( 7 )$$

The constitutive model of stress relaxation and seawater aging of a GINA gasket constructed by using the above method could be substituted into ANSYS finite element software by programming or commands, Solid185 units were used to simulate rubber test pieces to simulate the aging process of the GINA gasket 3, so as to predict the aging life of the GINA gasket 3, and the parameters of the modified constitutive model were verified by comparative analysis of test and numerical simulation results.

That is, based on curves of the aging coefficient k changing with the aging time at different aging temperatures (50° C., 60° C., 70° C. and 80° C.) (in the figure, the degree centigrade unit is provided, and should be used uniformly), and taking 50° C. as a reference temperature, that is, α_{323K}=1, the value of b was obtained by linear regression with x=1/T₀−1/T and y=ln α_{T} by means of Origin software. Then, α_{TNormal}=exp[b(1/T₀−1/T)] at normal temperature could be obtained by using formula ln α=b(1/T₀−1/T).

Based on a fitting equation ln P=f(t) of mechanical properties with the aging time at T₀=50° C., to when P=σ₀−k_{pw} was calculated, t₀=t_{Normal}/α_{TNormal}=58450 days, that is, the service life of the GINA gasket 3 at normal temperature is 160 years.

The aging life of the GINA gasket obtained according to the patent of the present application can reach 160 years. The service life obtained according to the patent of the present application is closer to an actual situation.

The above described are merely preferred embodiments of the present application, and are not intended to limit the present application. Any modification, equivalent substitution, improvement, and the like without departing from the spirit and principle of the present application should fall within the protection scope of the present application.

What is claimed is:

1. A method for constructing a time-varying constitutive model of a seawater-aged GINA gasket for an immersed tube tunnel, comprising the following steps:
(1) selecting GINA gasket test pieces, and performing an accelerated seawater aging test of each GINA gasket test piece at different temperatures under a designed compression amount, to obtain stress relaxation curves at different aging temperatures;
(2) determining a contact stress σ of the aged GINA gasket and an initial contact stress go of the GINA gasket based on the stress relaxation curves in step (1), and determining an aging coefficient k of the GINA gasket based on k=σ/σ₀; and determining, based on P=σ−σ₀, an aging performance change value P of rubber used for the GINA gasket;
(3) obtaining a curve of ln P changing with a time t at normal temperature based on a time-temperature superposition principle, to obtain an equation P=exp(f(t)), wherein f(t) is a function of the aging performance change value P changing with the time t; and determining P=(1−k)σ₀ based on a correlation between the aging coefficient k of the GINA gasket and the aging performance change value P of the rubber used for the GINA gasket, that is, a normal temperature aging coefficient k_{Normal}=1−exp(f(t))/σ₀ of the GINA gasket is obtained;
(4) performing a uniaxial tensile test of the GINA gasket at an ambient temperature of 23° C. and a tensile speed of 500 mm/min, and determining a stress-strain relation curve of the GINA gasket;
(5) modifying the stress-strain relation curve in step (4) by using the normal temperature aging coefficient k_{Normal} of the GINA gasket, to obtain a stress-strain relation curve of a full aging cycle; and
(6) constructing a constitutive model of stress relaxation and seawater aging of the GINA gasket with reference to a Mooney-Rivlin model based on the stress-strain relation curve of the full aging cycle in step (5):
$$σ = 2 ( {λ}^{2} - {λ}^{1} ) ( f ( t ) + g ( t ) {λ}^{- 1} ) ,$$
wherein t is an aging time; λ is an elongation ratio of the GINA gasket; f(t) is a function of C₁₀ changing with the time t; g(t) is a function of C₀₁ changing with the time t; and C₁₀ and C₀₁ are Rivlin coefficients of the Mooney-Rivlin model, with values determined by the stress-strain relation curve of the full aging cycle.

2. The method for constructing a time-varying constitutive model of a seawater-aged GINA gasket for an immersed tube tunnel according to claim 1, wherein step (6) specifically comprises:
(6.1) determining ci based on the uniaxial tensile test of the GINA gasket in step (4), determining three elongation ratios λᵢ of the GINA gasket based on εᵢ, which are denoted as λ₁, λ₂, and λ₃, and calculating Green strain invariants I₁ and I₂, as follows:
$${λ}_{i} = 1 + {ε}_{i} , \qquad ( 1 )$$
$${I}_{1} = {λ}_{1}^{2} + {λ}_{2}^{2} + {λ}_{3}^{2} , \qquad ( 2 )$$
$$and {I}_{2} = {λ}_{1}^{2} {λ}_{2}^{2} + {λ}_{2}^{2} {λ}_{3}^{2} + {λ}_{1}^{2} {λ}_{3}^{2} , \qquad ( 3 )$$
wherein I₁ is a first strain invariant, and I₂ is a second strain invariant; λ₁, λ₂ and λ₃ represent an elongation ratio in an X-axis direction, an elongation ratio in a Y-axis direction, and an elongation ratio in a Z-axis direction respectively; εᵢ is a strain, i=1, 2 or 3, wherein ε₁ is a strain in the X-axis direction, ε₂ is a strain in the Y-axis direction, and ε₃ is a strain in the Z-axis direction;
(6.2) determining a strain energy density W as follows based on the Green strain invariants I₁ and I₂:
$$W = {C}_{10} ( {I}_{1} - 3 ) + {C}_{01} ( {I}_{2} - 3 ) \qquad ( 4 )$$
wherein C₁₀ and C₀₁ are Rivlin coefficients of the Mooney-Rivlin model, with values determined by the stress-strain relation curve of the full aging cycle;
(6.3) obtaining, by using a relation between a Kirchhoff stress and a Green strain:
$$σ = \frac{\partial W}{\partial {ε}_{i}} = \frac{\partial W}{\partial {I}_{1}} \frac{\partial {I}_{1}}{\partial {ε}_{i}} + \frac{\partial W}{\partial {I}_{2}} \frac{\partial {I}_{2}}{\partial {ε}_{i}} ,$$
a relation between the contact stress σ of the aged GINA gasket and the elongation ratio λ as follows:
$$σ = 2 ( {λ}^{2} - {λ}^{1} ) ( \frac{\partial W}{\partial {I}_{1}} + \frac{1}{λ} \frac{\partial W}{\partial {I}_{2}} ) \qquad ( 5 )$$
calculating partial derivatives of I₁ and I₂ by using formula (4), to obtain
$$\frac{\partial W}{\partial {I}_{1}} = {C}_{10} and \frac{\partial W}{\partial {I}_{2}} = {C}_{01} ,$$
and then obtaining a relation between the contact stress σ of the aged GINA gasket and the elongation ratio λ as follows:
$$σ = 2 ( {λ}^{2} - {λ}^{1} ) ( {C}_{10} + {C}_{01} {λ}^{- 1} ) , \qquad ( 6 )$$
(6.4) identifying parameters of formula (6) by using a nonlinear least square method based on the stress-strain relation curve of the full aging cycle by means of Origin software, to obtain values of C₁₀ and C₀₁ in a full life cycle tᵢ, obtaining functions f(t) and g(t) of C₁₀ and C₀₁ changing with a time based on curves of C₁₀ and C₀₁ changing with the aging time, and then constructing the constitutive model of stress relaxation and seawater aging of the GINA gasket:
$$σ = 2 ( {λ}^{2} - {λ}^{1} ) ( f ( t ) + g ( t ) {λ}^{- 1} ) . \qquad ( 7 )$$

3. The method for constructing a time-varying constitutive model of a seawater-aged GINA gasket for an immersed tube tunnel according to claim 2, wherein in step (1), conditions of the accelerated seawater aging test are as follows:
the gasket with a Shore hardness of 50 HS is placed on a bottom plate, and restrained by a ballast plate and a pressure strip; with reference to a TB/T2843-2010 standard, a press with a rated load of 3000 kN is used to add a load to the gasket; after a compression amount reaches 125.0 mm, the ballast plate is controlled by using a medium plate, a liquid gas pressure sensor is placed on the medium plate and pressed by using a top plate; the top plate, the medium plate and the bottom plate are fixed and then integrally placed in a sealed polypropylene plastic cabin, which is filled with natural seawater by ⅔, and a contact stress of the GINA gasket in the seawater is collected in real time within a range of 50-80° C.

4. The method for constructing a time-varying constitutive model of a seawater-aged GINA gasket for an immersed tube tunnel according to claim 2, wherein specific conditions of the uniaxial tensile test in step (4) are as follows:
the GINA gasket after seawater aging in step (1) is taken out, cooled with liquid nitrogen, and prepared into a dumbbell-shaped test piece based on GB/T528-2009, the test piece is coated with a lubricant, and the tensile test is performed by using a universal testing machine at a normal temperature of 23° C. at a speed of 500 mm/min.

5. The method for constructing a time-varying constitutive model of a seawater-aged GINA gasket for an immersed tube tunnel according to claim 4, wherein the dumbbell-shaped test piece has a total length of 100.0 mm and a thickness of 2.0 mm, and a test section has an initial test length of 20.0 mm.
